(19) United States
(12) Patent Application Publication
(10) Pub. No.: US 2025/0311228 A1
(43) Pub. Date: Oct. 2, 2025

(54) SEMICONDUCTOR DEVICE

(71) Applicant: Samsung Electronics Co., Ltd., Suwon-si (KR)

(72) Inventor: Jeon Il LEE, Suwon-si (KR)

(73) Assignee: Samsung Electronics Co., Ltd., Suwon-si (KR)

(21) Appl. No.: 18/925,837

(22) Filed: Oct. 24, 2024

(30) Foreign Application Priority Data
Mar. 27, 2024 (KR) 10-2024-0042052

(51) Int. Cl. H10B 51/30; H10B 51/20; H10B 51/40; H10B 51/50

(52) U.S. Cl. CPC H10B 51/30; H10B 51/20; H10B 51/40; H10B 51/50

(57) ABSTRACT

A semiconductor device includes, a substrate including a cell region and a peripheral circuit region; a vertical structure extending perpendicular to an upper surface of the substrate, the vertical structure including a bit line and a source line spaced apart in a first direction; a word line extending in the first direction; a channel layer between the bit line and the word line, and between the source line and the word line, the channel layer connected between the bit line and the source line; a ferroelectric layer between the word line and the channel layer; a control circuit on the substrate; a source line connection wire connected to the source line and the control circuit; and a bit line connection wire connected to the bit line and the control circuit. The source line connection wire and the bit line connection wire cross on a plane.

### CROSS-REFERENCE TO RELATED APPLICATION

This application claims priority to and the benefit of Korean Patent Application No. 10-2024-0042052 filed at the Korean Intellectual Property Office on Mar. 27, 2024, the entire contents of which are incorporated herein by reference.

### BACKGROUND

The present disclosure relates to a semiconductor device.

As an autonomous vehicle, a humanoid robot, an artificial intelligence mobile phone, or the like is developed, a semiconductor device capable of performing an artificial neural network calculation is being developed. An example of the semiconductor device capable of performing the artificial neural network calculation may be a neural processing unit (NPU). The NPU may be a calculation device, and may perform a calculation by exchanging data with a memory device. Power consumption is inevitable for the calculation device to exchange data with the memory device. Accordingly, in order to reduce electric power consumed in data transmission, research is being conducted on a neuromorphic element capable of performing the artificial neural network calculation within the memory device.

### SUMMARY

Some example embodiments are to provide a semiconductor device capable of performing a deep neural network (DNN) calculation with ultra-low electric power and in which memory cells are stacked in three dimensions to be highly integrated.

A semiconductor device according to some example embodiments includes, a substrate including a cell region and a peripheral circuit region; a vertical structure extending in a direction perpendicular to an upper surface of the substrate at the cell region, the vertical structure including a bit line and a source line spaced apart in a first direction parallel to the upper surface of the substrate; a word line extending in the first direction at one side of the vertical structure; a channel layer between the bit line and the word line, between the source line and the word line, the channel layer is connected between the bit line and the source line; a ferroelectric layer between the word line and the channel layer; a control circuit on the substrate at the peripheral circuit region; a source line connection wire connected to the source line and the control circuit; and a bit line connection wire connected to the bit line and the control circuit. The source line connection wire and the bit line connection wire cross on a plane.

A semiconductor device according to some example embodiments includes, a substrate including a cell region and a peripheral circuit region; a vertical structure extending in a direction perpendicular to an upper surface of the substrate at the cell region, the vertical structure including a bit line and a source line spaced apart in a first direction parallel to the upper surface of the substrate; a word line extending in the first direction at one side of the vertical structure; a channel layer between the bit line and the word line and between the source line and the word line, the channel layer is connected between the bit line and the source line; a ferroelectric layer between the word line and the channel layer; a control circuit on the substrate at the peripheral circuit region; and a source line connection wire and a bit line connection wire extending in a direction parallel to the upper surface of the substrate, the source line connection wire and the bit line connection wire are stacked above the vertical structure. The source line connection wire extends in the first direction, and the bit line connection wire extends in a second direction orthogonal to the first direction.

A semiconductor device according to some example embodiment includes, a substrate including a cell region and a peripheral circuit region; a vertical structure extending in a direction perpendicular to an upper surface of the substrate at the cell region, the vertical structure including a bit line and a source line spaced apart in a first direction parallel to the upper surface of the substrate; a word line extending in the first direction at one side of the vertical structure; a channel layer between the bit line and the word line and between the source line and the word line, the channel layer is connected between the bit line and the source line; a ferroelectric layer between the word line and the channel layer; a control circuit on the substrate at the peripheral circuit region; an analog-to-digital converter on the substrate and connected to the control circuit; a source line connection wire that is above the vertical structure and is connected to the source line and the control circuit; and a bit line connection wire above the vertical structure and connected to the bit line and the analog-to-digital converter. The source line connection wire and the bit line connection wire are at different layers, one of the source line connection wire and the bit line connection wire extends in a direction parallel to the word line, and an other of the source line connection wire and the bit line connection wire extends in a direction crossing the word line.

According to some example embodiments, a semiconductor device may perform a deep neural network (DNN) calculation with ultra-low electric power without exchanging data with a separate calculation device.

According to some example embodiments, the semiconductor device may implement a higher integrated memory device capable of performing the DNN calculation with the ultra-low electric power.

### BRIEF DESCRIPTION OF THE DRAWINGS

FIG. 1 is a perspective view of a semiconductor device according to some example embodiments.

FIG. 2 is a block diagram showing a signal flow between components of the semiconductor device of FIG. 1.

FIG. 3 is a plan view of the semiconductor device of FIG. 1.

FIG. 4 is a cross-sectional view taken along a line A-A′ of FIG. 3.

FIG. 5 is a cross-sectional view taken along a line B-B′ of FIG. 3.

FIG. 6 is a block diagram showing a signal flow between components of the semiconductor device according to some example embodiments.

FIG. 7 is a plan view of the semiconductor device of FIG. 6.

FIG. 8 is a cross-sectional view taken along a line A-A′ of FIG. 7.

FIGS. 9, 11, 13, 15, 17, 19, 21, and 23 are plan views showing a method for manufacturing the semiconductor device according to some example embodiments.

FIGS. 10, 12, 14, 16, 18, 20, 22, and 24 are cross-sectional views showing the method for manufacturing the semiconductor device according to some example embodiments.

### DETAILED DESCRIPTION

Some example embodiments of the present disclosure will be described more fully hereinafter with reference to the accompanying drawings so that those skilled in the art easily implement the example embodiments. The present disclosure may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

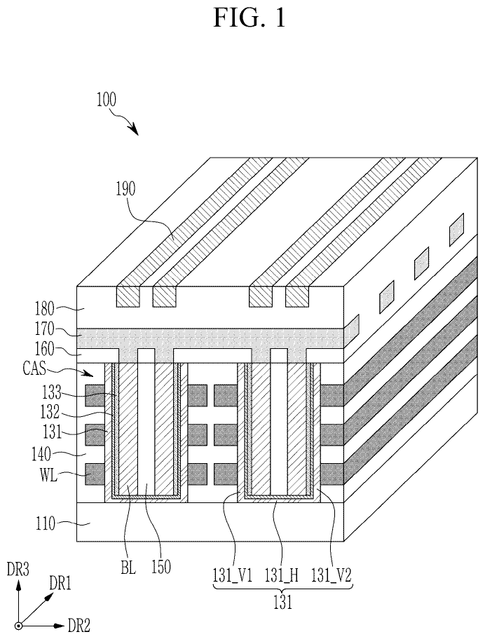

Hereinafter, a semiconductor device 100 according to some example embodiments will be described with reference to FIGS. 1 to 5.

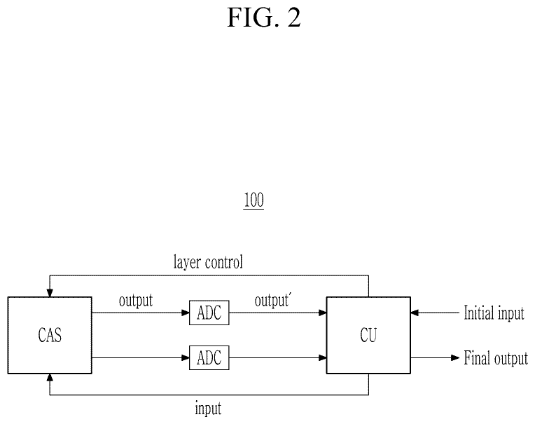

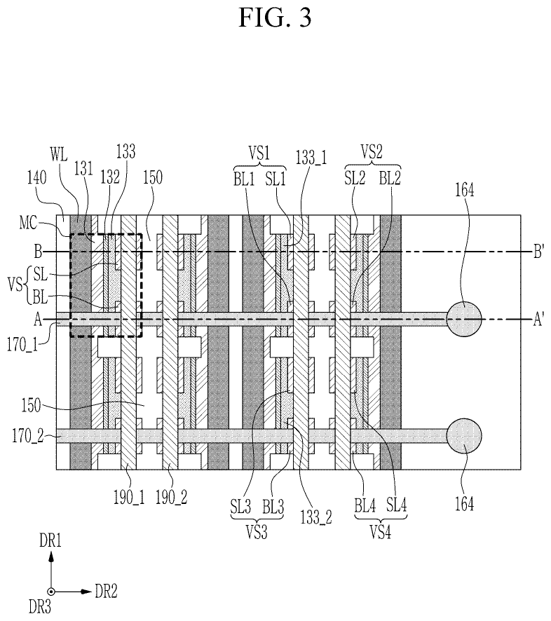

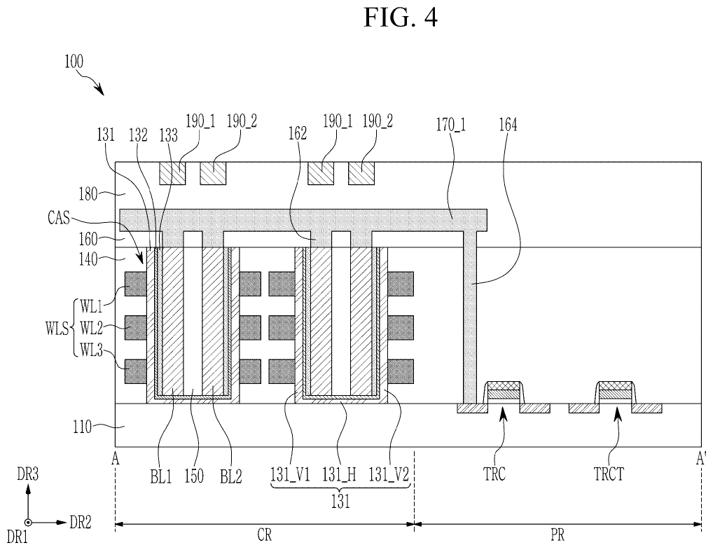

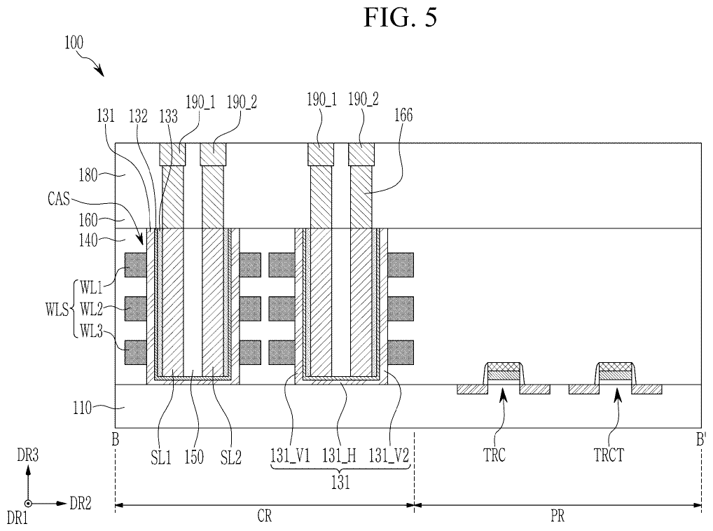

FIG. 1 is a perspective view of the semiconductor device according to some example embodiments. FIG. 2 is a block diagram showing a signal flow between components of the semiconductor device of FIG. 1. FIG. 3 is a plan view of the semiconductor device of FIG. 1. FIG. 4 is a cross-sectional view taken along a line A-A′ of FIG. 3. FIG. 5 is a cross-sectional view taken along a line B-B′ of FIG. 3. For convenience of description, illustration of some insulating layers of the semiconductor device 100 is omitted in FIG. 3.

Referring to FIGS. 1 to 5, the semiconductor device 100 according to some example embodiments may include a substrate 110, a cell array structure CAS, an analog-to-digital converter ADC, and a control circuit CU. The cell array structure CAS, the analog-to-digital converter ADC, and the control circuit CU may be disposed above or on the substrate 110. The analog-to-digital converter ADC may be connected between the cell array structure CAS and the control circuit CU.

The substrate 110 may be a semiconductor substrate made of silicon, germanium, and/or silicon-germanium. The substrate 110 may be a bulk silicon substrate, a silicon-on-insulator (SOI) substrate, a germanium substrate, a germanium-on-insulator (GOI) substrate, a silicon-germanium substrate, or a substrate with an epitaxial thin film obtained by performing selective epitaxial growth (SEG).

The cell array structure CAS may be disposed at a cell region CR of the substrate 110, and the analog-to-digital converter ADC and the control circuit CU may be disposed at a peripheral circuit region PR of the substrate 110. On a plane, the peripheral circuit region PR may be disposed next to the cell region CR. The control circuit CU may be disposed next to the cell array structure CAS on a plane. The analog-to-digital converter ADC may be disposed next to the cell array structure CAS on a plane. For example, the analog-to-digital converter ADC may be disposed between the cell array structure CAS and the control circuit CU on a plane, but the present disclosure is not limited thereto.

The cell array structure CAS may include a plurality of memory cells MC that may store data. The cell array structure CAS may have a structure in which a plurality of layers are stacked on an upper surface of the substrate 110. The memory cells MC may be disposed in an array form at each layer of the cell array structure CAS.

The analog-to-digital converter ADC and the control circuit CU may be circuit patterns formed on the substrate 110. The analog-to-digital converter ADC may be the circuit pattern configured to convert an analog signal to a digital signal. The control circuit CU may be the circuit pattern configured to control the cell array structure CAS. The control circuit CU may control the cell array structure CAS to write data in the plurality of memory cells MC of the cell array structure CAS and read data stored in the plurality of memory cells MC.

According to some example embodiments, the control circuit CU may control the cell array structure CAS to perform a calculation (or a computation) based on data stored in the plurality of memory cells MC. According to some example embodiments, the control circuit CU may perform a deep neural network (DNN) calculation by controlling an input signal input to the cell array structure CAS. Each layer of the cell array structure CAS may correspond to a plurality of hidden layers of the deep neural network. Weight values of each hidden layer of the deep neural network may be respectively stored in the memory cells MC of each layer of the cell array structure CAS. The control circuit CU may perform a calculation of each hidden layer by inputting an input signal to each layer of the cell array structure CAS to obtain an output signal. The control circuit CU may perform calculations of the plurality of hidden layers by inputting an output signal of the previous layer as an input signal of the next layer. An output signal output from the last layer of the cell array structure CAS may correspond to a final calculation result of the deep neural network for an input signal input to a first layer of the cell array structure CAS.

In some example embodiments, the control circuit CU may input an input signal (input) to the cell array structure CAS based on an initial input signal (Initial input) received from the outside. For example, the input signal (input) input to the cell array structure CAS may be a voltage. The control circuit CU may input a layer control signal (layer control) turning on/off a transistor constituting the memory cells of each layer to each layer of the cell array structure CAS. The analog-to-digital converter ADC may convert an output signal (output) output from the cell array structure CAS from an analog signal to a digital signal. For example, the output signal (output) output from the cell array structure CAS may be an electric current. The control circuit CU may receive an output signal (output′) of the cell array structure CAS converted to a digital signal from the analog-to-digital converter ADC. The control circuit CU may output a final output signal (Final output) based on the output signal (output′) of the cell array structure CAS received from the analog-to-digital converter ADC.

Although FIG. 2 shows two analog-to-digital converters ADC, the present disclosure is not limited thereto. The number of analog-to-digital converters ADC may be variously changed in response to the number of output signals output from the cell array structure CAS.

According to some example embodiments, the analog-to-digital converter ADC may include a converter transistor TRC. The control circuit CU may include a control transistor TRCT. In FIG. 1 and FIG. 5, the converter transistor TRC may correspond to the analog-to-digital converter ADC, and the control transistor TRCT may correspond to the control circuit CU. In FIG. 1 and FIG. 5, one converter transistor TRC and one control transistor TRCT are shown for convenience of description, but the present disclosure is not limited thereto. Each of the analog-to-digital converter ADC and the control circuit CU may further include more transistors or a circuit element other than the transistor.

According to some example embodiments, the cell array structure CAS may include a vertical structure VS including a bit line BL and a source line SL, a word line structure WLS including a word line WL, and a ferroelectric layer 131 and a channel layer 133 disposed between the vertical structure VS and the word line structure WLS. According to some example embodiments, the cell array structure CAS may further include a gate insulating layer 132 between the ferroelectric layer 131 and the channel layer 133.

According to some example embodiments, the vertical structure VS may include the bit line BL and the source line SL extending in a third direction DR3 perpendicular to an upper surface of the substrate 110. The bit line BL and the source line SL may have a pillar shape extending in the third direction DR3. The bit line BL and the source line SL may be spaced apart in a first direction DR1 parallel to the upper surface of the substrate 110. The channel layer 133 and an insulating pattern 150 that will be described later may be disposed between the bit line BL and the source line SL.

Each of the bit line BL and the source line SL may include a conductive material. For example, each of the bit line BL and the source line SL may include at least one selected from a doped semiconductor material (e.g., doped silicon or doped germanium), conductive metal nitride (e.g., titanium nitride or tantalum nitride), a metal (e.g., tungsten, titanium, or tantalum), and/or a metal-semiconductor compound (e.g., tungsten silicide, cobalt silicide, or titanium silicide), but the present disclosure is not limited thereto.

The word line structure WLS may be disposed at one side of the vertical structure VS. The word line structure WLS may include the word line WL extending in the first direction DR1 parallel to the upper surface of the substrate 110. The word line WL may include a conductive material. For example, the word line WL may include at least one selected from a doped semiconductor material, conductive metal nitride, a metal, and a metal-semiconductor compound, but the present disclosure is not limited thereto.

The word line structure WLS may include a plurality of word lines WL1, WL2, and WL3 stacked in the third direction DR3 perpendicular to the upper surface of the substrate 110. Each of the plurality of word lines WL1, WL2, and WL3 may extend in the first direction DR1 parallel to the upper surface of the substrate 110.

According to some example embodiments, each of the plurality of layers of the cell array structure CAS may be defined by the word line WL. Each layer of the cell array structure CAS may include the plurality of word lines WL1, WL2, and WL3.

According to some example embodiments, each of the plurality of memory cells MC of the cell array structure CAS may include the source line SL, the bit line BL, the word line WL, and the ferroelectric layer 131, the gate insulating layer 132, and the channel layer 133 disposed between the source line SL, the bit line BL, and the word line WL.

According to some example embodiments, an on/off signal may be applied to the word line WL, and the input signal may be applied to the source line SL. According to some example embodiments, the output signal may be output from the bit line BL. The memory cells MC of the layer of the cell array structure CAS corresponding to the word line WL to which the on signal is applied may be turned on. A voltage may be applied between the bit line BL and the source line SL of each of the memory cells MC that is turned on.

The channel layer 133 may be disposed between the word line WL and the bit line BL, and between the word line WL and the source line SL. The channel layer 133 may cover side surfaces of the bit line BL and the source line SL, and may extend in the third direction DR3 perpendicular to the upper surface of the substrate 110. The channel layer 133 may extend in the first direction DR1 from the side surface of the bit line BL to the side surface of the source line SL on a plane. The channel layer 133 may protrude in a second direction DR2 parallel to the upper surface of the substrate 110 between the bit line BL and the source line SL. The channel layer 133 may be connected between the bit line BL and the source line SL. The second direction DR2 may be a direction that crosses the first direction DR1, and for example, the second direction DR2 may be orthogonal to the first direction DR1.

The channel layer 133 may include at least one of a semiconductor material, an amorphous oxide semiconductor material, and a two-dimensional material. In some example embodiments, the channel layer 133 may include at least one selected from polysilicon, doped silicon (Si), silicon germanium (SiGe), and/or a semiconductor formed by selective epitaxial growth (SEG). The channel layer 133 may have a single layer or multi-layer structure.

In some example embodiments, the channel layer 133 may include an amorphous oxide semiconductor material, and for example, the channel layer 133 may include a compound of at least two metals selected from zinc (Zn), indium (In), gallium (Ga), and tin (Sn) and oxygen (O). For example, the channel layer 133 may include at least one selected from indium gallium zinc oxide (IGZO), indium tin zinc oxide (ITZO), Sn-IGZO, IWO, CuS₂, CuSe₂, WSe₂, IZO, ZTO, and/or YZO, but the present disclosure is not limited thereto.

In some example embodiments, the channel layer 133 may include a two-dimensional material. For example, the channel layer 133 may include metal chalcogenide, transition metal chalcogenide, graphene, or phosphorene.

According to some example embodiments, if a gate-on signal is applied to the word line WL of the memory cell MC and a predetermined or alternatively desired voltage is respectively applied to the bit line BL and the source line SL, a current may flow from the source line SL to the bit line BL through the channel layer 133 of the memory cell MC.

The ferroelectric layer 131 may be disposed between the channel layer 133 and the word line WL. According to some example embodiments, the ferroelectric layer 131 may extend along the first direction DR1. A thickness (or a width along the second direction DR2) of the ferroelectric layer 131 may not be constant on a plane. On a plane, a thickness of a portion of the ferroelectric layer 131 that overlaps the channel layer 133 in the second direction DR2 may be thicker than a thickness of a portion of the ferroelectric layer 131 that does not overlap the channel layer 133 in the second direction DR2.

According to some example embodiments, the ferroelectric layer 131 may include a horizontal portion 131_H parallel to the upper surface of the substrate 110 and vertical portions 131_V1 and 131_V2 extending from the horizontal portion 131_H in the third direction DR3 perpendicular to the upper surface of the substrate 110. The vertical portions 131_V1 and 131_V2 may include the first vertical portion 131_V1 and the second vertical portion 131_V2 spaced apart in the second direction DR2.

The ferroelectric layer 131 may include a ferroelectric material. In some example embodiments, the ferroelectric material may include an Hf compound. For example, the Hf compound may be Hf-based oxide. The Hf-based oxide may further include at least one impurity selected from Zr, Si, Al, Y, Gd, La, Sc, and/or Sr. For example, the ferroelectric material may include HfO₂, HfZnO, HfSiO, HfSiON, HfTaO, HfTiO, HfZrO, or a combination thereof. The ferroelectric layer 131 may have an orthorhombic phase. The ferroelectric layer 131 may include a single layer, a multilayer in which two or more types of ferroelectric layers are stacked, or a multilayer in which a ferroelectric layer and a dielectric material layer are stacked.

According to some example embodiments, the ferroelectric layer 131 may have various polarization states depending on a voltage applied between the bit line BL and the source line SL and the word line WL. According to some example embodiments, a current value flowing from the source line SL to the bit line BL through the channel layer 133 may be determined based on the polarization state of the ferroelectric layer 131.

According to some example embodiments, the gate insulating layer 132 may be disposed between the channel layer 133 and the ferroelectric layer 131. The gate insulating layer 132 may have a shape corresponding to a profile of the ferroelectric layer 131. The gate insulating layer 132 may be disposed between the vertical portions 131_V1 and 131_V2 of the ferroelectric layer 131 and the channel layer 133. The gate insulating layer 132 may be disposed between the horizontal portion 131_H of the ferroelectric layer 131 and the channel layer 133. The gate insulating layer 132 may be disposed between the horizontal portion 131_H of the ferroelectric layer 131 and lower surfaces of the bit line BL and the source line SL. The gate insulating layer 132 may be disposed between the horizontal portion 131_H of the ferroelectric layer 131 and a lower surface of the insulating pattern 150 that will be described later. The gate insulating layer 132 may extend in the second direction DR2 between the first vertical portion 131_V1 and the second vertical portion 131_V2 of the ferroelectric layer 131. A thickness of the gate insulating layer 132 may be thinner than thicknesses of the ferroelectric layer 131 and the channel layer 133.

For example, the gate insulating layer 132 may include a silicon oxide layer, a silicon oxynitride layer, a high dielectric layer having a higher dielectric constant than that of the silicon oxide layer, or a combination thereof. For example, the high dielectric layer may include metal oxide or metal oxynitride.

According to some example embodiments, the cell array structure CAS may include a first vertical structure VS1 and a second vertical structure VS2 that are spaced apart in the second direction DR2. The first vertical structure VS1 may include a first bit line BL1 and a first source line SL1. The second vertical structure VS2 may include a second bit line BL2 and a second source line SL2. The first bit line BL1 may face the second bit line BL2 in the second direction DR2, and the first source line SL1 may face the second source line SL2 in the second direction DR2.

The ferroelectric layer 131 may surround the first vertical structure VS1 and the second vertical structure VS2. The first vertical structure VS1 and the second vertical structure VS2 may be disposed above the horizontal portion 131_H of the ferroelectric layer 131. The first vertical structure VS1 and the second vertical structure VS2 may be disposed between the first vertical portion 131_V1 and the second vertical portion 131_V2 of the ferroelectric layer 131.

The channel layer 133 may be disposed between the first vertical structure VS1 and the first vertical portion 131_V1 of the ferroelectric layer 131, and between the second vertical structure VS2 and the second vertical portion 131_V2 of the ferroelectric layer 131. The channel layer 133 may extend from between the first source line SL1 and the first bit line BL1 to between the second source line SL2 and the second bit line BL2 above the horizontal portion 131_H of the ferroelectric layer 131.

According to some example embodiments, the cell array structure CAS may include a third vertical structure VS3 spaced apart from the first vertical structure VS1 in the first direction DR1. The cell array structure CAS may include a fourth vertical structure VS4 spaced apart from the second vertical structure VS2 in the first direction DR1. The third vertical structure VS3 and the fourth vertical structure VS4 may be separated in the second direction DR2.

The third vertical structure VS3 may include a third bit line BL3 and a third source line SL3. The fourth vertical structure VS4 may include a fourth bit line BL4 and a fourth source line SL4. The third bit line BL3 may face the fourth bit line BL4 in the second direction DR2, and the third source line SL3 may face the fourth source line SL4 in the second direction DR2.

The first source line SL1, the first bit line BL1, the third source line SL3, and the third bit line BL3 may be disposed along the first direction DR1. The second source line SL2, the second bit line BL2, the fourth source line SL4, and the fourth bit line BL4 may be disposed along the first direction DR1. That is, the source line SL and the bit line BL may be alternately disposed along the first direction DR1.

The ferroelectric layer 131 may surround the third vertical structure VS3 and the fourth vertical structure VS4. The third vertical structure VS3 and the fourth vertical structure VS4 may be disposed above the horizontal portion 131_H of the ferroelectric layer 131. The third vertical structure VS3 and the fourth vertical structure VS4 may be disposed between the first vertical portion 131_V1 and the second vertical portion 131_V2 of the ferroelectric layer 131.

The ferroelectric layer 131 may extend along the first direction DR1 at one side of each of the first vertical structure VS1 and the third vertical structure VS3. The ferroelectric layer 131 may extend along the first direction DR1 at one side of each of the second vertical structure VS2 and the fourth vertical structure VS4. Each of the one side of each of the first vertical structure VS1 and the third vertical structure VS3 and the one side of each of the second vertical structure VS2 and the fourth vertical structure VS4 may be one side along the second direction DR2. For example, the first vertical portion 131_V1 of the ferroelectric layer 131 may extend in the first direction DR1 from the one side of each of the first vertical structure VS1 and the third vertical structure VS3, and the second vertical portion 131_V2 of the ferroelectric layer 131 may extend in the first direction DR1 from the one side of each of the second vertical structure VS2 and the fourth vertical structure VS4.

The channel layer 133 may be disposed between the third vertical structure VS3 and the first vertical portion 131_V1 of the ferroelectric layer 131, and between the fourth vertical structure VS4 and the second vertical portion 131_V2 of the ferroelectric layer 131.

The cell array structure CAS may include a plurality of channel layers 133_1 and 133_2. The plurality of channel layers 133_1 and 133_2 may include the first channel layer 133_1 disposed between the first vertical structure VS1 and the second vertical structure VS2 and the ferroelectric layer 131, and the second channel layer 133_2 disposed between the third vertical structure VS3 and the fourth vertical structure VS4 and the ferroelectric layer 131. The first channel layer 133_1 and the second channel layer 133_2 may be spaced apart in the first direction DR1.

The insulating pattern 150 may be disposed above the horizontal portion 131_H of the ferroelectric layer 131. The gate insulating layer 132 may be disposed between the horizontal portion 131_H of the ferroelectric layer 131 and the insulating pattern 150. The insulating pattern 150 may be disposed between the first vertical portion 131_V1 and the second vertical portion 131_V2 of the ferroelectric layer 131. The insulating pattern 150 may cover a side surface and an upper surface of the channel layer 133 between the first vertical portion 131_V1 and the second vertical portion 131_V2 of the ferroelectric layer 131.

The plurality of channel layers 133_1 and 133_2 may be spaced apart in the first direction DR1 between the first vertical portion 131_V1 and the second vertical portion 131_V2 of the ferroelectric layer 131 by the insulating pattern 150. The plurality of vertical structures VS1, VS2, VS3, and VS4 may be spaced apart between the first vertical portion 131_V1 and the second vertical portion 131_V2 of the ferroelectric layer 131 by the insulating pattern 150. The insulating pattern 150 may be disposed between the first bit line BL1 and the second bit line BL2 facing in the second direction DR2, and between the first source line SL1 and the second source line SL2 facing in the second direction DR2. The insulating pattern 150 may be disposed between the third bit line BL3 and the fourth bit line BL4 facing each other in the second direction DR2, and between the third source line SL3 and the fourth source line SL4 facing each other in the second direction DR2. The insulating pattern 150 may be disposed between the first bit line BL1 and the third source line SL3 facing each other in the first direction DR1. The insulating pattern 150 may be disposed between the second bit line BL2 and the fourth source line SL4 facing each other in the first direction DR1.

For example, the first vertical structure VS1 and the second vertical structure VS2 may be spaced apart in the second direction DR2 between the first vertical portion 131_V1 and the second vertical portion 131_V2 of the ferroelectric layer 131 by the insulating pattern 150. The third vertical structure VS3 and the fourth vertical structure VS4 may be spaced apart in the second direction DR2 between the first vertical portion 131_V1 and the second vertical portion 131_V2 of the ferroelectric layer 131 by the insulating pattern 150.

For example, the first vertical structure VS1 and the third vertical structure VS3 may be spaced apart in the first direction DR1 between the first vertical portion 131_V1 and the second vertical portion 131_V2 of the ferroelectric layer 131 by the insulating pattern 150. The second vertical structure VS2 and the fourth vertical structure VS4 may be spaced apart in the first direction DR1 between the first vertical portion 131_V1 and the second vertical portion 131_V2 of the ferroelectric layer 131 by the insulating pattern 150.

For example, the insulating pattern 150 may include at least one of silicon oxide, silicon nitride, and/or silicon oxynitride, but the present disclosure is not limited thereto.

The cell array structure CAS may include a plurality of word line structures WLS. Each of the plurality of word line structures WLS may be common to the plurality of vertical structures disposed along the first direction. For example, the plurality of word line structures WLS may include a first word line structure common to the first vertical structure VS1 and the third vertical structure VS3, and a second word line structure common to the second vertical structure VS2 and the fourth vertical structure VS4. The first word line structure may be disposed at one side of the first vertical portion 131_V1 of the ferroelectric layer 131, and the second word line structure may be disposed at one side of the second vertical portion 131_V2 of the ferroelectric layer 131.

The first word line structure and the second word line structure may be disposed at opposite sides of a surface where the first vertical portion 131_V1 and the second vertical portion 131_V2 of the ferroelectric layer 131 face each other. For example, the first word line structure may be adjacent to an outer side surface of the first vertical portion 131_V1 and the second word line structure may be adjacent to an outer side surface of the second vertical portion 131_V2. The first channel layer 133_1 may be disposed between the first word line structure and the first vertical structure VS1, and between the second word line structure and the second vertical structure VS2. The second channel layer 133_2 may be disposed between the first word line structure and the third vertical structure VS3, and between the second word line structure and the fourth vertical structure VS4. The first vertical portion 131_V1 of the ferroelectric layer 131 may be disposed between the first word line structure and the first channel layer 133_1, and between the first word line structure and the second channel layer 133_2. The second vertical portion 131_V2 of the ferroelectric layer 131 may be disposed between the first word line structure and the first channel layer 133_1, and between the second word line structure and the second channel layer 133_2.

According to some example embodiments, the plurality of vertical structures VS1, VS2, VS3, and VS4 and the plurality of channel layers 133_1 and 133_2 may be disposed inside the ferroelectric layer 131 surrounded by the horizontal portion 131_H of the ferroelectric layer 131 and the first vertical portion 131_V1 and the second vertical portion 131_V2 extending from the horizontal portion 131_H in the third direction DR3. The plurality of word line structures WLS may be disposed outside the ferroelectric layer 131.

According to some example embodiments, the cell array structure CAS may include a plurality of ferroelectric layers 131. The plurality of vertical structures VS1, VS2, VS3, and VS4 and the plurality of channel layers 133_1 and 133_2 may be disposed inside each of the plurality of ferroelectric layers 131. The plurality of word line structures WLS may be disposed outside each of the plurality of ferroelectric layers 131.

According to some example embodiments, a cell insulating layer 140 may surround the cell array structure CAS. The cell insulating layer 140 may fill an outer space of the plurality of ferroelectric layers 131. The cell insulating layer 140 may surround the plurality of word line structures WLS outside the plurality of ferroelectric layers 131. The cell insulating layer 140 may cover an upper surface of the substrate 110 disposed outside the cell array structure CAS.

A bit line connection wire 170 and a source line connection wire 190 may be disposed above the cell array structure CAS and the cell insulating layer 140. According to some example embodiments, the bit line connection wire 170 and the source line connection wire 190 may be stacked along the third direction DR3 perpendicular to the upper surface of the substrate 110. The bit line connection wire 170 and the source line connection wire 190 may be disposed at different layers. According to some example embodiments, the source line connection wire 190 may be stacked above the bit line connection wire 170, but the present disclosure is not limited thereto, and the bit line connection wire 170 may be stacked above the source line connection wire 190.

According to some example embodiments, the bit line connection wire 170 and the source line connection wire 190 may extend in a direction parallel to the upper surface of the substrate 110, and may extend in a direction crossing each other on a plane. According to some example embodiments, the bit line connection wire 170 may extend in the second direction DR2, and the source line connection wire 190 may extend in the first direction DR1, but the present disclosure is not limited thereto.

According to some example embodiments, a first interlayer insulating layer 160 may be disposed on the cell array structure CAS and the cell insulating layer 140. The first interlayer insulating layer 160 may cover an upper surface of the cell array structure CAS and an upper surface of the cell insulating layer 140. A plurality of bit line connection wires 170 extending in the second direction DR2 may be disposed on the first interlayer insulating layer 160. Each of the plurality of bit line connection wires 170 may pass above upper surfaces of a plurality of bit lines BL that are spaced apart and disposed along the second direction DR2 of the cell array structure CAS. For example, the plurality of bit line connection wires 170 may include a first bit line connection wire 170_1 passing over upper surfaces of first bit lines BL1 and second bit lines BL2, and a second bit line connection wire 170_2 passing over upper surfaces of third bit lines BL3 and fourth bit lines BL4. The first interlayer insulating layer 160 may be further disposed between the plurality of bit line connection wires 170.

A second interlayer insulating layer 180 may be disposed on the plurality of bit line connection wires 170 and the first interlayer insulating layer 160. The second interlayer insulating layer 180 may cover upper surfaces of the plurality of bit line connection wires 170 and the first interlayer insulating layer 160. A plurality of source line connection wires 190 extending in the first direction DR1 may be disposed on the second interlayer insulating layer 180. The bit line connection wire 170 and the source line connection wire 190 may be spaced apart from each other in the third direction DR3 perpendicular to the upper surface of the substrate 110. According to some example embodiments, the plurality of bit line connection wires 170 and the plurality of source line connection wires 190 may be separated in the third direction DR3 by the second interlayer insulating layer 180.

Each of the plurality of source line connection wires 190 may pass over upper surfaces of a plurality of source lines SL that are spaced apart and disposed along the first direction DR1 of the cell array structure CAS. For example, the plurality of source line connection wires 190 may include a first source line connection wire 190_1 passing over upper surfaces of first source lines SL1 and third source lines SL3, and a second source line connection wire 190_2 passing over upper surfaces of second source lines SL2 and fourth source lines SL4. The second interlayer insulating layer 180 may be further disposed between the plurality of source line connection wires 190.

According to some example embodiments, each of the first interlayer insulating layer 160 and the second interlayer insulating layer 180 may be made of a single layer or a multilayer. For example, each of the first interlayer insulating layer 160 and the second interlayer insulating layer 180 may include at least one of a silicon oxide layer, a silicon nitride layer, and/or a silicon oxynitride layer. In FIG. 1 and FIG. 4, a boundary between the first interlayer insulating layer 160 and the second interlayer insulating layer 180 is not distinguished, but the present disclosure is not limited thereto. For example, the boundary between the first interlayer insulating layer 160 and the second interlayer insulating layer 180 may be distinguished.

According to some example embodiments, the bit line connection wire 170 may be connected to the plurality of bit lines BL spaced apart and disposed along the second direction DR2 through a plurality of bit line contacts 162 penetrating the first interlayer insulating layer 160. The bit line connection wire 170 may connect the plurality of bit lines BL that are spaced apart and disposed along the second direction DR2. For example, the first bit line connection wire 170_1 may connect the first bit lines BL1 and the second bit lines BL2. The second bit line connection wire 170_2 may connect the third bit lines BL3 and the fourth bit lines BL4.

According to some example embodiments, the source line connection wire 190 may be connected to the plurality of source lines SL spaced apart and disposed along the first direction DR1 through a plurality of source line contacts 166 penetrating the first interlayer insulating layer 160 and the second interlayer insulating layer 180. The source line connection wire 190 may connect the plurality of source lines SL that are spaced apart and disposed along the first direction DR1. For example, the first source line connection wire 190_1 may connect the first source lines SLland the third source lines SL3. The second source line connection wire 190_2 may connect the second source lines SL2 and the fourth source lines SL4.

According to some example embodiments, the bit line connection wire 170 and the source line connection wire 190 may connect the cell array structure CAS and the control circuit CU. The bit line connection wire 170 and the source line connection wire 190 may be connected to the control circuit CU through a through via 164 that penetrates the cell insulating layer 140. Each of the bit line connection wire 170, the source line connection wire 190, the bit line contact 162, the source line contact 166, and the through via 164 may include a conductive material.

Although not shown in the drawings, the source line connection wire 190 may be connected to the control circuit CU by a through via that penetrates the second interlayer insulating layer 180, the first interlayer insulating layer 160, and the cell insulating layer 140. The control circuit CU may transfer the input signal to the source line connection wire 190 through the through via. The source line connection wire 190 may transfer the input signal to the plurality of source lines SL connected to the source line connection wire 190 through the source line contact 166.

According to some example embodiments, the bit line connection wire 170 may be connected to the analog-to-digital converter ADC connected between the cell array structure CAS and the control circuit CU. The bit line connection wire 170 may be connected to the analog-to-digital converter ADC through the through via 164. Referring to FIG. 1 and FIG. 4, the through via 164 may penetrate the first interlayer insulating layer 160 and the cell insulating layer 140 to connect the bit line connection wire 170 to the converter transistor TRC. An output signals output from the plurality of bit lines BL may be transferred to the bit line connection wire 170 connected to the plurality of bit lines BL through the bit line contact 162. The output signal may be transferred from the bit line connection wire 170 to the analog-to-digital converter ADC through the through via 164. The analog-to-digital converter ADC may receive the output signal from the bit line connection wire 170 through the through via 164. The analog-to-digital converter ADC may convert the output signal from an analog signal to a digital signal. The analog-to-digital converter ADC may transfer the converted output signal to the control circuit CU.

The converter transistor TRC and the control transistor TRCT may be electrically connected. According to some example embodiments, the converter transistor TRC and the control transistor TRCT may form a single circuit pattern, but the present disclosure is not limited thereto. According to some example embodiments, the semiconductor device 100 may further include a wiring layer connecting the converter transistor TRC and the control transistor TRCT at the peripheral circuit region PR.

Referring to FIG. 2, the semiconductor device 100 may include a plurality of analog-to-digital converters ADC. Each of the plurality of analog-to-digital converters ADC may be connected to each of the plurality of bit line connection wires 170. The control circuit CU may be connected to each of the plurality of analog-to-digital converters ADC. The control circuit CU may input the input signal to the cell array structure CAS or may output the final output signal (Final output) based on output signals (output) transferred from the plurality of analog-to-digital converters ADC.

In the above-described example embodiments, the cell array structure CAS is above or on the substrate 110 and the analog-to-digital converter ADC and the control circuit CU are disposed next to the cell array structure CAS, but the present disclosure is not limited thereto. According to some example embodiments, in the semiconductor device 100, the analog-to-digital converter ADC and the control circuit CU and an insulating layer covering the analog-to-digital converter ADC and the control circuit CU may be disposed above or on the substrate 110, and the cell array structure CAS may be disposed above or on the insulating layer. The disposition structure may be referred to as a cell-on-peri (COP) structure. In the COP structure, the through via 164 may be connected to the analog-to-digital converter ADC or the control circuit CU by further penetrating the insulating layer covering the analog-to-digital converter ADC and the control circuit CU.

According to some example embodiments, the semiconductor device 100 may include the cell array structure CAS in which the plurality of memory cells including the ferroelectric layer 131 are stacked in three dimensions, the control circuit CU, and the source line connection wire 190 and the bit line connection wire 170 connecting the cell array structure CAS and the control circuit CU and extending in a direction crossing each other. Thus, the semiconductor device 100 may implement a deep neural network (DNN) in hardware.

According to some example embodiments, the semiconductor device 100 may apply an on/off signal to the word lines WL of each of the plurality of layers of the cell array structure CAS to turn on the memory cells MC of any one of the plurality of layers and turn off the memory cells MC of the remaining layers of the plurality of layers, and may obtain output signals output from the bit lines BL of the turned-on memory cells MC based on the input signal input to the source lines SL of the turned-on memory cells MC and polarization states of the ferroelectric layers 131 of the turned-on memory cells MC. In this case, the plurality of layers of the cell array structure CAS may correspond to the plurality of hidden layers of the DNN, and the polarization state of the ferroelectric layer 131 may correspond to a weight value in the calculation of each hidden layer. According to some example embodiments, the source line connection wire 190 inputting the input signal to the source lines SL and the bit line connection wire 170 outputting the output signal from the bit lines BL may extend in a direction perpendicular to each other. Thus, each of output signals for the input signals respectively input to the source lines SL may be output from each of the bit lines BL corresponding to the source lines SL, and the output signals respectively output from the bit lines BL may be merged through the bit line connection wire 170 to be transferred to the analog-to-digital converter ADC and the control circuit CU. The semiconductor device 100 may use output signals output from the memory cells MC of the previous layer as input signals of the memory cells MC of the next layer. The semiconductor device 100 may perform a DNN calculation by repeating the above-described operation for all layers of the cell array structure CAS.

According to some example embodiments, the semiconductor device 100 may perform the DNN calculation with ultra-low electric power based on data stored in the plurality of memory cells MC and data input to the plurality of memory cells MC without exchanging data with a separate calculation device. According to some example embodiments, the semiconductor device 100 may implement a highly integrated or high-density memory device capable of performing the DNN calculation with the ultra-low electric power by stacking the plurality of memory cells MC including the ferroelectric layer 131 in a direction perpendicular to the upper surface of the substrate 110.

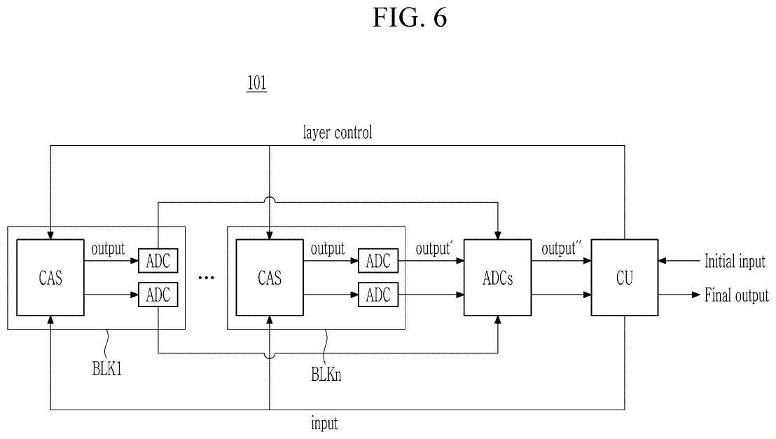

Hereinafter, a semiconductor device 101 according to some example embodiments will be described with reference to FIGS. 6 to 8.

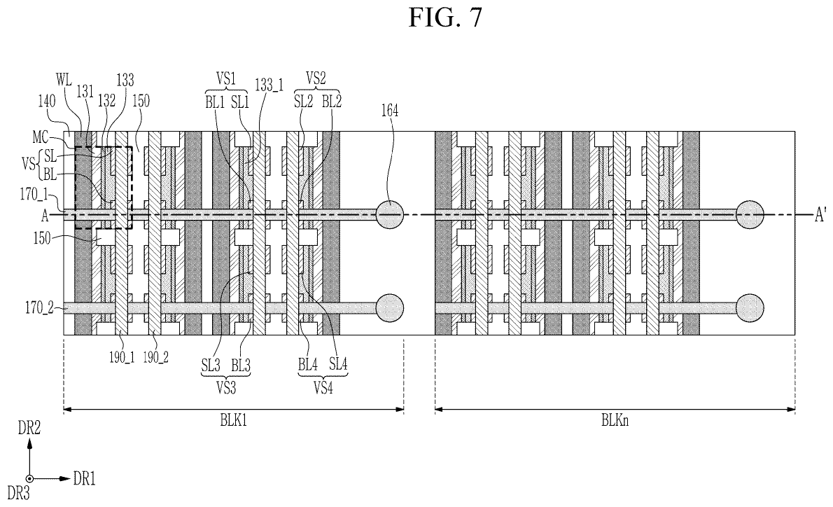

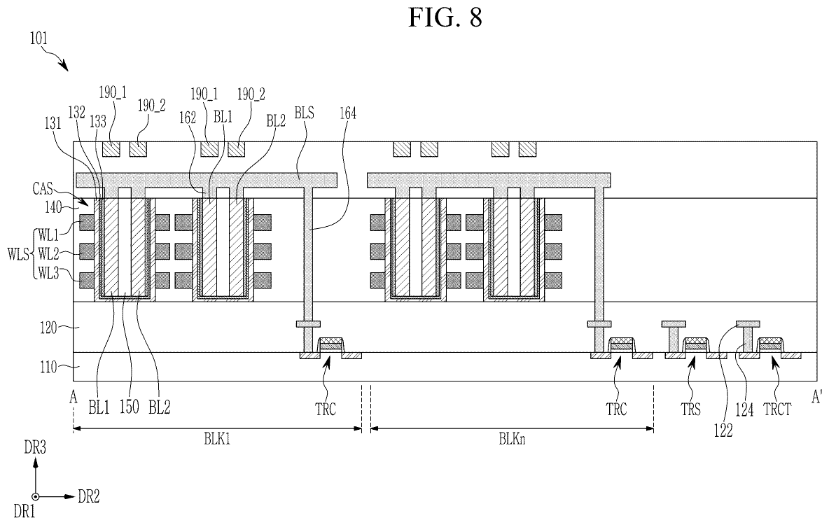

FIG. 6 is a block diagram showing a signal flow between components of the semiconductor device according to some example embodiments. FIG. 7 is a plan view of the semiconductor device of FIG. 6. FIG. 8 is a cross-sectional view taken along a line A-A′ of FIG. 7.

FIG. 6 may be a view corresponding to FIG. 2, FIG. 7 may be a view corresponding to FIG. 3, and FIG. 8 may be a view corresponding to FIG. 4. A structure of the cell array structure CAS shown in FIG. 1 may be equally applied to the semiconductor device 101 of FIGS. 6 to 8.

Hereinafter, the semiconductor device 101 of FIGS. 6 to 8 will be described focusing on a difference between the semiconductor device 101 of FIGS. 6 to 8 and the semiconductor device 100 of FIGS. 1 to 5, and a content described with reference to the semiconductor device 101 of FIGS. 6 to 8 to which the content described above with reference to FIGS. 1 to 5 may be equally applied will be briefly described or omitted. A component among components of the semiconductor device 101 of FIGS. 6 to 8 that is the same as that of the semiconductor device 100 of FIGS. 1 to 5 may be referred to by the same reference symbol.

Referring to FIGS. 6 to 8, the semiconductor device 101 according to some example embodiments may include a plurality of cell blocks BLK1-BLKn, a control circuit CU, and a summing circuit ADCs. The plurality of cell blocks BLK1-BLKn may include n cell blocks, n being a natural number. Each of the plurality of cell blocks BLK1-BLKn may include a cell array structure CAS, an analog-to-digital converter ADC, a bit line connection wire 170 connecting the cell array structure CAS to the analog-to-digital converter ADC, and a source line connection wire 190 connecting the cell array structure CAS to the control circuit CU.

According to some example embodiments, the summing circuit ADCs may be a circuit pattern configured to sum digital signals converted by the analog-to-digital converter ADC of each of the plurality of cell blocks BLK1-BLKn. The summing circuit ADCs may be connected between the analog-to-digital converter ADC and the control circuit CU of each of the plurality of cell blocks BLK1-BLKn.

The control circuit CU may input an input signal (input) to the cell array structure CAS of each of the plurality of cell blocks BLK1-BLKn based on an initial input signal (Initial input) received from the outside. The control circuit CU may input a layer control signal (layer control) turning on/off a transistor constituting memory cells of each layer to each layer of the cell array structure CAS of each of the plurality of cell blocks BLK1-BLKn. The analog-to-digital converter ADC of each of the plurality of cell blocks BLK1-BLKn may convert an output signal (output) output from the cell array structure CAS from an analog signal to a digital signal. The control circuit CU may receive an output signal (output′) of each of the plurality of cell blocks BLK1-BLKn converted to the digital signal from the analog-to-digital converter ADC of each of the plurality of cell blocks BLK1-BLKn. The control circuit CU may transfer the output signal (output′) received from the analog-to-digital converter ADC of each of the plurality of cell blocks BLK1-BLKn to the summing circuit ADCs. The summing circuit ADCs may transfer an output signal (output ″) that is a sum of output signals (output′) of the plurality of cell blocks BLK1-BLKn to the control circuit CU. The control circuit CU may output a final output signal (Final output) based on the output signal (output″) received from the summing circuit ADCs.

In some example embodiments, the summing circuit ADCs may be omitted. In other words, each of the analog-to-digital converter ADC of the plurality of cell blocks BLK1-BLKn may be directly connected to the control circuit CU. The control circuit CU may output the final output signal (Final output) based on the output signal (output′) received from the analog-to-digital converter ADC of each of the plurality of cell blocks BLK1-BLKn.

According to some example embodiments, the summing circuit ADCs may include a summing transistor TRS. In FIG. 7, the summing transistor TRS may correspond to the summing circuit ADCs. Although one summing transistor TRS is shown in FIG. 7 for convenience of description, the present disclosure is not limited thereto, and the summing circuit ADCs may further include more transistors or a circuit element other than the transistor.

Hereinafter, a description will focus on some example embodiments in which the semiconductor device 100 includes the summing circuit ADCs, but the present disclosure is not limited thereto, and the following description may be equally or similarly applied to some example embodiments in which the summing circuit ADCs is omitted.

According to some example embodiments, a converter transistor TRC, the summing transistor TRS, and a control transistor TRCT of each of the plurality of cell blocks BLK1-BLKn may be disposed above or on a substrate 110. According to some example embodiments, a peripheral circuit insulating layer 120 covering the converter transistor TRC, the summing transistor TRS, and the control transistor TRCT may be disposed on the substrate 110.

According to some example embodiments, a wiring layer 122 and a lower contact 124 may be disposed within the peripheral circuit insulating layer 120. The wiring layer 122 may include wires connecting the converter transistor TRC, the summing transistor TRS, and the control transistor TRCT of each of the plurality of cell blocks BLK1-BLKn. Although the wiring layer 122 is shown as a single layer in FIG. 7, the present disclosure is not limited thereto, and the wiring layer 122 may be formed of a plurality of layers. In this case, the plurality of layers may be spaced apart from each other in a third direction DR3 perpendicular to an upper surface of the substrate 110 by the peripheral circuit insulating layer 120.

The lower contact 124 may penetrate the peripheral circuit insulating layer 120 to connect the wiring layer 122 to the converter transistor TRC, the summing transistor TRS, and the control transistor TRCT. The wiring layer 122 and the lower contact 124 may include a conductive material. The converter transistor TRC, the summing transistor TRS, and the control transistor TRCT of each of the plurality of cell blocks BLK1-BLKn may be electrically connected by the wiring layer 122 and the lower contact 124.

According to some example embodiments, the cell array structure CAS of each of the plurality of cell blocks BLK1-BLKn may be disposed on the peripheral circuit insulating layer 120. The structure of the cell array structure CAS shown in FIG. 1 may be equally applied to the cell array structure CAS of each of the plurality of cell blocks BLK1-BLKn.

According to some example embodiments, a cell insulating layer 140 surrounding the cell array structure CAS of each of the plurality of cell blocks BLK1-BLKn may be disposed on the peripheral circuit insulating layer 120. The cell insulating layer 140 may cover an upper surface of the peripheral circuit insulating layer 120 disposed outside the plurality of cell blocks BLK1-BLKn.

According to some example embodiments, the bit line connection wire 170 and the source line connection wire 190 may be stacked above the cell array structure CAS of each of the plurality of cell blocks BLK1-BLKn and the cell insulating layer 140. A first interlayer insulating layer 160 may be disposed above the cell array structure CAS of each of the plurality of cell blocks BLK1-BLKn and the cell insulating layer 140, and a plurality of bit line connection wires 170 extending in a second direction DR2 may be disposed above the first interlayer insulating layer 160. For example, the plurality of bit line connection wires 170 may include a first bit line connection wire 170_1 connecting a first bit line BL1 and a second bit line BL2 spaced apart from each other in the second direction DR2, and a second bit line connection wire 170_2 connecting a third bit line BL3 and a fourth bit line BL4 spaced apart from each other in the second direction DR2. The bit line connection wire 170 may be connected to a bit line BL through a bit line contact 162 that penetrates the first interlayer insulating layer 160. The first interlayer insulating layer 160 may be disposed between the plurality of bit line connection wires 170 of each of the plurality of cell blocks BLK1-BLKn.

According to some example embodiments, a second interlayer insulating layer 180 may be disposed above the plurality of bit line connection wires 170 of each of the plurality of cell blocks BLK1-BLKn and the first interlayer insulating layer 160, and a plurality of source line connection wires 190 extending in a first direction DR1 may be disposed above the second interlayer insulating layer 180. For example, the plurality of source line connection wires 190 may include first source line connection wires 190_1 connecting a first source line SL1 and a third source line SL3 spaced apart from each other in the first direction DR1, and second source line connection wires 190_2 connecting a second source line SL2 and a fourth source line SL4 spaced apart from each other in the first direction DR1. The source line connection wire 190 may be connected to a source line SL through the source line contact 166 of FIG. 5 that penetrates the second interlayer insulating layer 180 and the first interlayer insulating layer 160. The second interlayer insulating layer 180 may be disposed between the plurality of source line connection wires 190 of each of the plurality of cell blocks BLK1-BLKn.

According to some example embodiments, the source line connection wire 190 of each of the plurality of cell blocks BLK1-BLKn does not appear at a cross-section of FIG. 8, but may be connected to the control transistor TRCT of each of the plurality of cell blocks BLK1 to BLKn through a through via. The through via connecting the source line connection wire 190 and the control transistor TRCT may penetrate the second interlayer insulating layer 180, the first interlayer insulating layer 160, the cell insulating layer 140, and the peripheral circuit insulating layer 120. The control circuit CU may transfer the input signal to the source line connection wire 190 of each of the plurality of cell blocks BLK1-BLKn through the through via.

According to some example embodiments, the bit line connection wire 170 of each of the plurality of cell blocks BLK1-BLKn may be connected to the converter transistor TRC of each of the plurality of cell blocks BLK1-BLKn through the through via 164. The through via 164 may connect the bit line connection wire 170 to the analog-to-digital converter ADC by penetrating the first interlayer insulating layer 160, the cell insulating layer 140, and the peripheral circuit insulating layer 120. The analog-to-digital converter ADC of each of the plurality of cell blocks BLK1-BLKn may convert the output signal transferred from the bit line connection wire 170 of each of the plurality of cell blocks BLK1-BLKn from an analog signal to a digital signal through the through via 164.

According to some example embodiments, the converted output signal (output′) output from the analog-to-digital converter ADC of each of a plurality of cell blocks BLK1-BLKn may be transferred to the summing circuit ADCs through the wiring layer 122 and the lower contact 124. The summing circuit ADCs may sum output signals of the plurality of cell blocks BLK1-BLKn. According to some example embodiments, the summed output signal (output ″) output from the summing circuit ADCs may be transferred to the control circuit CU through the wiring layer 122 and the lower contact 124.

According to some example embodiments, the control circuit CU may input the input signal to the cell array structure CAS of each of the plurality of cell blocks BLK1-BLKn or may output the final output signal (Final output) based on the converted output signal (output′) output from the analog-to-digital converter ADC of each of the plurality of cell blocks BLK1-BLKn or the summed output signal (output″) output from the summing circuit ADCs.

According to some example embodiments, the semiconductor device 101 may perform a DNN calculation with ultra-low electric power based on data stored in a plurality of memory cells MC and data input to the plurality of memory cells MC without exchanging data with a separate calculation device. According to some example embodiments, the semiconductor device 101 may implement a highly integrated or high-density memory device capable of performing the DNN calculation with the ultra-low electric power by stacking the plurality of memory cells MC including a ferroelectric layer 131 in a direction perpendicular to the upper surface of the substrate 110.

For example, as the number of parameters used in the DNN calculation increases, the number of memory cells MC included in the cell array structure CAS of the semiconductor device 101 may increase. As the number of memory cells MC increases, lengths of the bit line connection wire 170 and the source line connection wire 190 that connect the cell array structure CAS and the control circuit CU may increase. If a length of the wire increases, a signal transferred through the wire may be attenuated.

The semiconductor device 101 according to some example embodiments may include the plurality of cell blocks BLK1-BLKn respectively including the cell array structure CAS divided into a plural number on a plane, and may include the analog-to-digital converter ADC within each cell block BLK. Thus, the semiconductor device 101 may convert an analog signal output in units of blocks to a digital signal, may sum the converted digital signals, and may transfer the summed digital signals to the control circuit CU to perform a more accurate DNN calculation.

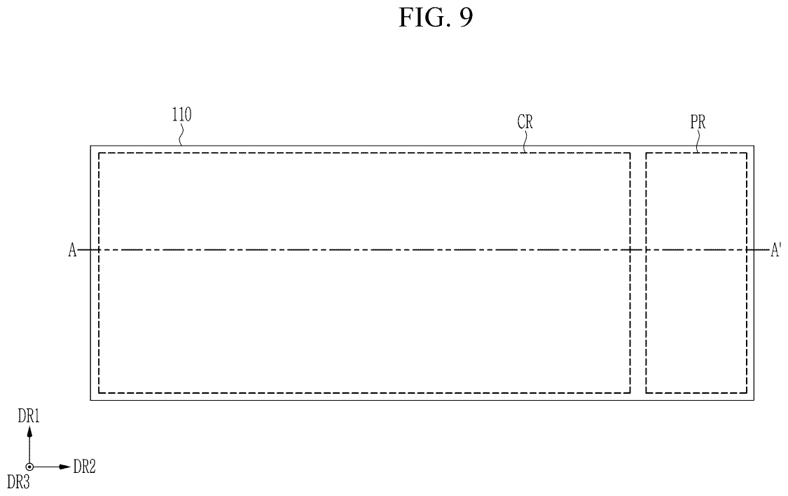

Hereinafter, a method for manufacturing the semiconductor device 100 of FIG. 1 according to some example embodiments will be described with reference to FIGS. 9 to 24.

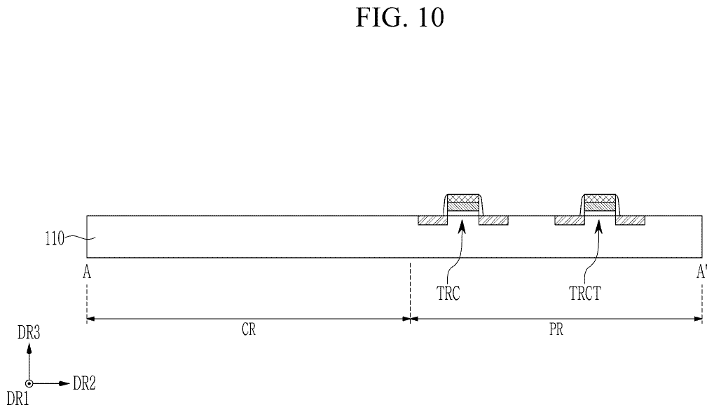

FIGS. 9, 11, 13, 15, 17, 19, 21, and 23 are plan views showing the method for manufacturing the semiconductor device according to some example embodiments. FIGS. 10, 12, 14, 16, 18, 20, 22, and 24 are cross-sectional views showing the method for manufacturing the semiconductor device according to some example embodiments. FIGS. 10, 12, 14, 16, 18, 20, 22, and 24 are cross-sectional views taken along lines A-A′ of FIGS. 9, 11, 13, 15, 17, 19, 21, and 23, respectively.

Referring to FIG. 9 and FIG. 10, the converter transistor TRC and a control transistor TRCT may be formed on the substrate 110. The converter transistor TRC may be a simplified representation of the analog-to-digital converter ADC of FIG. 2. The control transistor TRCT may be a simplified representation of the control circuit CU of FIG. 2. The converter transistor TRC and the control transistor TRCT may be electrically connected.

The substrate 110 may include the cell region CR and the peripheral circuit region PR. The peripheral circuit region PR may be disposed next to the cell region CR. The converter transistor TRC and the control transistor TRCT may be formed at the peripheral circuit region PR of the substrate 110.

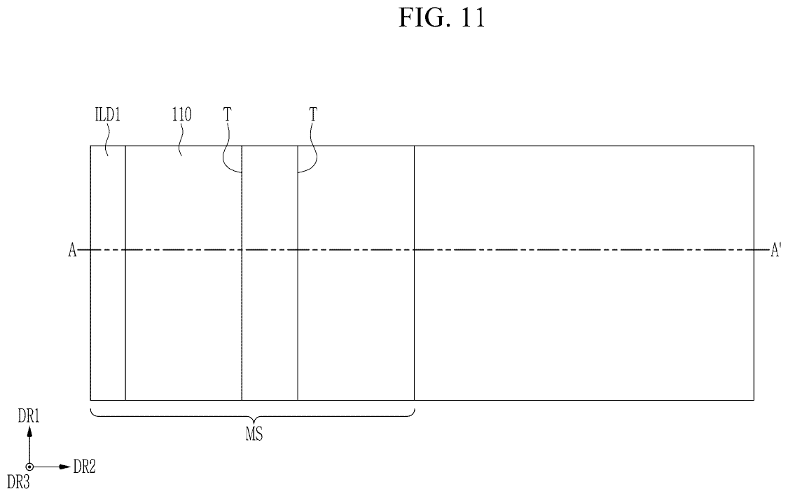

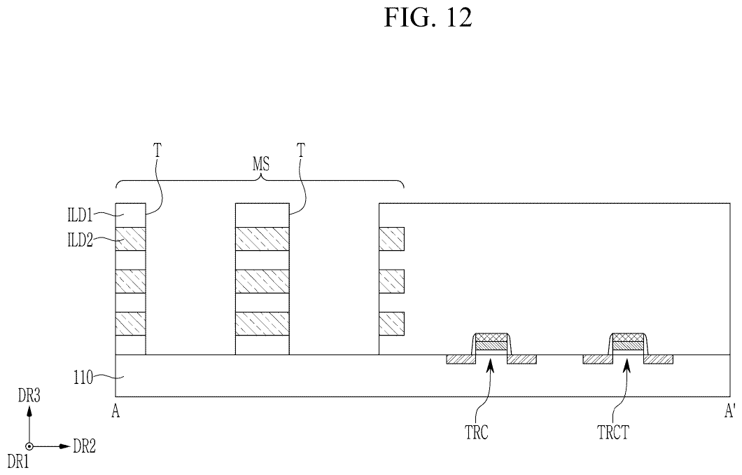

Referring to FIG. 11 and FIG. 12, a mold structure MS may be formed on the substrate 110. The mold structure MS may be formed at the cell region CR of FIG. 9 of the substrate 110. The mold structure MS may include a plurality of first insulating layers ILD1 and a plurality of second insulating layers ILD2 stacked in the third direction DR3 perpendicular to the upper surface of the substrate 110. The first insulating layer ILD1 and the second insulating layer ILD2 may include different insulating materials with etch selectivity. For example, the first insulating layer ILD1 may be a silicon oxide layer and the second insulating layer ILD2 may be a silicon nitride layer, but the present disclosure is not limited thereto.

The first insulating layer ILD1 may extend from the cell region CR of FIG. 9 to the peripheral circuit region PR of FIG. 9. In the peripheral circuit region PR of FIG. 9, the first insulating layer ILD1 may cover upper surfaces of the converter transistor TRC, the control transistor TRCT, and the substrate 110.

Next, trenches T penetrating the mold structure MS may be formed. For example, the mold structure MS may be anisotropic etched to form the trenches T penetrating the mold structure MS in the third direction DR3. The trench T may have a line shape extending in the first direction DR1 parallel to the upper surface of the substrate 110. Both side surfaces of the trench T may face each other in the second direction DR2 crossing (e.g., perpendicular to) the first direction DR1. Side surfaces of the plurality of first insulating layers ILD1 and the plurality of second insulating layers ILD2 may be exposed by the trench T.

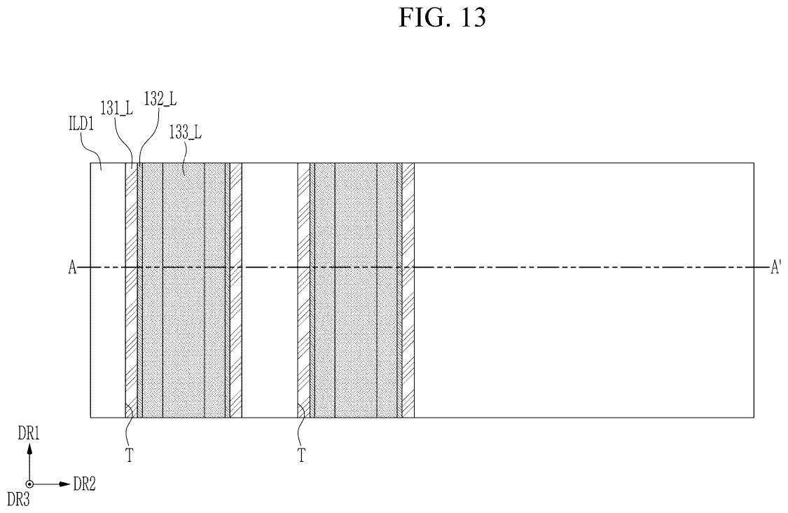

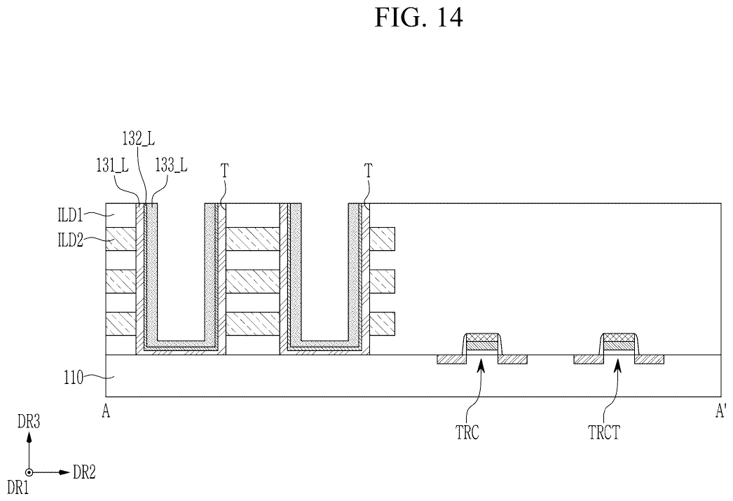

Referring to FIG. 13 and FIG. 14, a ferroelectric material layer 131_L, a gate insulating material layer 132_L, and a channel material layer 133_L may be sequentially formed within the trenches T.

The ferroelectric material layer 131_L may be formed to conformally cover lower surfaces and inner surfaces of the trenches T through a deposition process such as atomic layer deposition (ALD) or chemical vapor deposition (CVD). The ferroelectric material layer 131_L may cover the upper surface of the substrate 110. The ferroelectric material layer 131_L may cover the side surfaces of the plurality of first insulating layers ILD1 and the plurality of second insulating layers ILD2 exposed by the trench T.

The ferroelectric material layer 131_L may include a ferroelectric material. In an in some example embodiments, the ferroelectric material layer 131_L may include an Hf compound. For example, the ferroelectric material may include HfO₂, HfZnO, HfSiO, HfSiON, HfTaO, HfTiO, HfZrO, or a combination thereof.

The gate insulating material layer 132_L may be formed to conformally cover the ferroelectric material layer 131_L through a deposition process such as atomic layer deposition (ALD) or chemical vapor deposition (CVD). For example, the gate insulating material layer 132_L may include silicon oxide, silicon oxynitride, a high dielectric constant material having a higher dielectric constant than that of silicon oxide, or a combination thereof.

The channel material layer 133_L may be formed to conformally cover the gate insulating material layer 132_L through a deposition process such as atomic layer deposition (ALD) or chemical vapor deposition (CVD). The channel material layer 133_L may include at least one of a semiconductor material, an amorphous oxide semiconductor material, and a two-dimensional material. For example, the channel material layer 133_L may include IGZO.

According to some example embodiments, the ferroelectric material layer 131_L may be deposited to cover an upper surface of the first insulating layer ILD1 that is farthest from the upper surface of the substrate 110. Subsequently, the gate insulating material layer 132_L and the channel material layer 133_L may be sequentially deposited on the ferroelectric material layer 131_L. Subsequently, portions of the ferroelectric material layer 131_L, the gate insulating material layer 132_L, and the channel material layer 133_L disposed at a level higher than that of the upper surface of the first insulating layer ILD1 may be removed through a chemical mechanical polishing (CMP) process. That is, upper surfaces of the ferroelectric material layer 131_L, the gate insulating material layer 132_L, and the channel material layer 133_L may be disposed at substantially the same level as that of the upper surface of the first insulating layer ILD1 that is farthest from the upper surface of the substrate 110.

Each of the ferroelectric material layer 131_L, the gate insulating material layer 132_L, and the channel material layer 133_L may include a horizontal portion covering a bottom surface of the trench T and parallel to the upper surface of the substrate 110 and vertical portions extending from the horizontal portion in the third direction DR3 and facing in the second direction DR2 of the trench T.

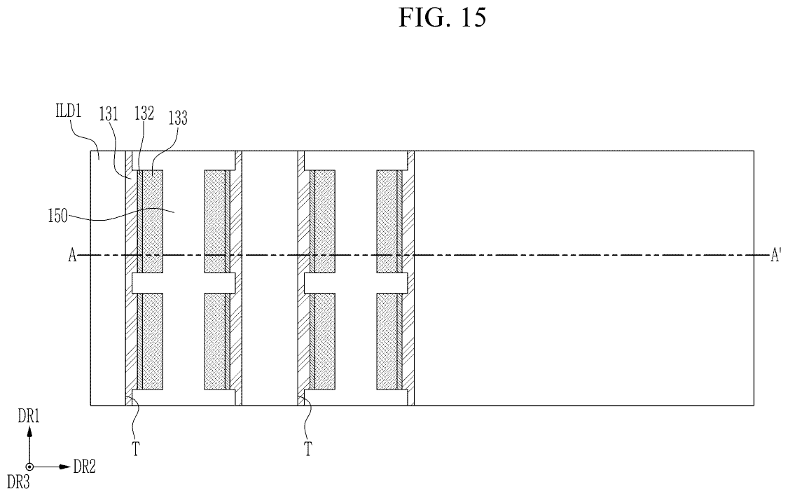

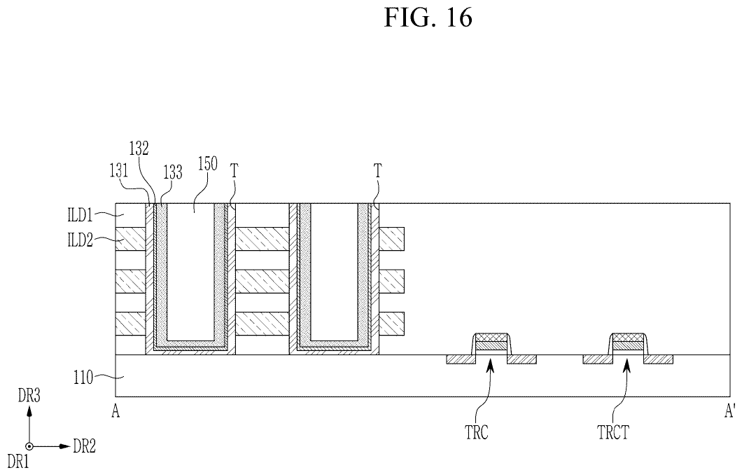

Referring to FIG. 15 and FIG. 16, a plurality of channel layers 133 may be formed by patterning the channel material layer 133_L.

According to some example embodiments, the channel material layer 133_L extending in the first direction DR1 may be cut through an anisotropic etching process to be separated into the plurality of channel layers 133 spaced apart in the first direction DR1. In the etching process, the gate insulating material layer 132_L may also be cut together with the channel material layer 133_L.

In an etching process, portions of the vertical portions of the ferroelectric material layer 131_L facing in the second direction DR2 may be removed. Accordingly, a thickness (e.g., a width along the second direction DR2) of each of the vertical portions of the ferroelectric layer 131 may not be constant on the plane. According to some example embodiments, a portion of the ferroelectric layer 131 overlapping the channel layer 133 in the second direction DR2 may be thicker than a portion of the ferroelectric layer 131 overlapping the channel layer 133 in the second direction DR2.

Next, the insulating pattern 150 filling the remaining space of the trench T may be formed. The insulating pattern 150 may include at least one of silicon oxide, silicon nitride, and silicon oxynitride.

According to some example embodiments, an insulating material layer including at least one of silicon oxide, silicon nitride, and silicon oxynitride may be deposited to fill the remaining space of the trench T. The insulating material layer may fill the remaining space of the trench T, and may cover an upper surface of the first insulating layer ILD1 that is farthest from the channel layer 133, the gate insulating layer 132, the ferroelectric layer 131, and the upper surface of the substrate 110. Subsequently, a portion of the insulating material layer disposed at a higher level than that of the upper surface of the first insulating layer ILD1 that is farthest from the channel layer 133, the gate insulating layer 132, the ferroelectric layer 131, and the upper surface of the substrate 110, may be removed through a chemical mechanical polishing (CMP) process. An upper surface of the insulating pattern 150 may be disposed at substantially the same level as that of the upper surface of the first insulating layer ILD1 that is farthest from the channel layer 133, the gate insulating layer 132, the ferroelectric layer 131, and the upper surface of the substrate 110.

The insulating pattern 150 may have a pillar shape extending in the third direction DR3. The insulating pattern 150 may be disposed between the vertical portions of the ferroelectric layer 131. The insulating pattern 150 may cover side surfaces of a plurality of gate insulating layers 132 and the plurality of channel layers 133 that are spaced apart in the first direction DR1. The plurality of channel layers 133 spaced apart in the first direction DR1 by the insulating pattern 150 may be insulated.

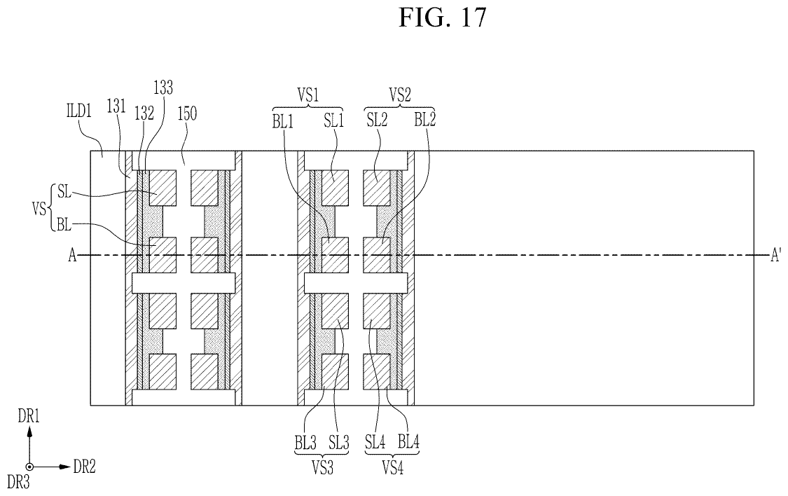

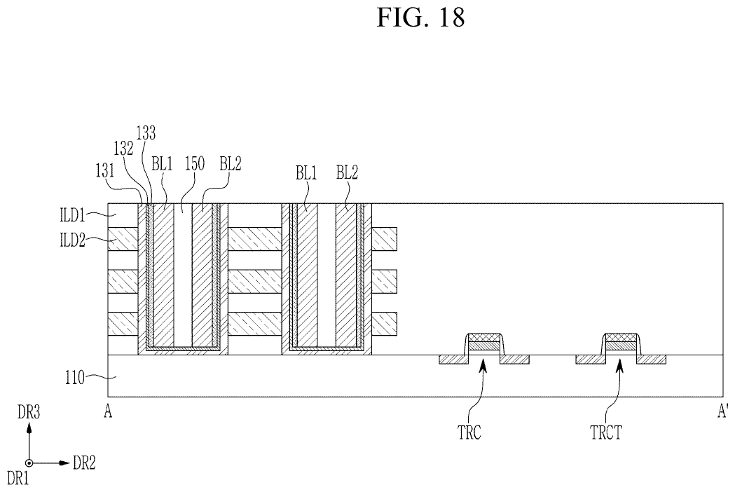

Referring to FIG. 17 and FIG. 18, each of a plurality of vertical structures VS including the source line SL and the bit line BL may be formed. The source line SL and the bit line BL may have a pillar shape penetrating the channel layer 133 and the insulating pattern 150 in the third direction DR3. The source line SL and the bit line BL may be spaced apart in the first direction DR1. The channel layer 133 may protrude in the second direction DR2 between the source line SL and the bit line BL.

Each of the source line SL and the bit line BL may include a conductive material. For example, each of the source line SL and the bit line BL may include at least one selected from a doped semiconductor material, conductive metal nitride, a metal, and a metal-semiconductor compound.

According to some example embodiments, the plurality of vertical structures VS may include the first vertical structure VS1 and the second vertical structure VS2 that are spaced apart in the second direction DR2 between the vertical portions of the ferroelectric layer 131. The first bit line BL1 of the first vertical structure VS1 and the second bit line BL2 of the second vertical structure VS2 may face each other in the second direction DR2. The first source line SL1 of the first vertical structure VS1 and the second source line SL2 of the second vertical structure VS2 may face each other in the second direction DR2.

According to some example embodiments, the plurality of vertical structures VS may include the third vertical structure VS3 spaced apart from the first vertical structure VS1 in the first direction DR1 and the fourth vertical structure VS4 spaced apart from the second vertical structure VS2 in the first direction DR1. The first source line SL1 and the first bit line BL1 of the first vertical structure VS1 and the third source line SL3 and the third bit line BL3 of the third vertical structure VS3 may be disposed along the first direction DR1. The second source line SL2 and the second bit line BL2 of the second vertical structure VS2 and the fourth source line SL4 and the fourth bit line BL4 of the fourth vertical structure VS4 may be disposed along the first direction DR1.

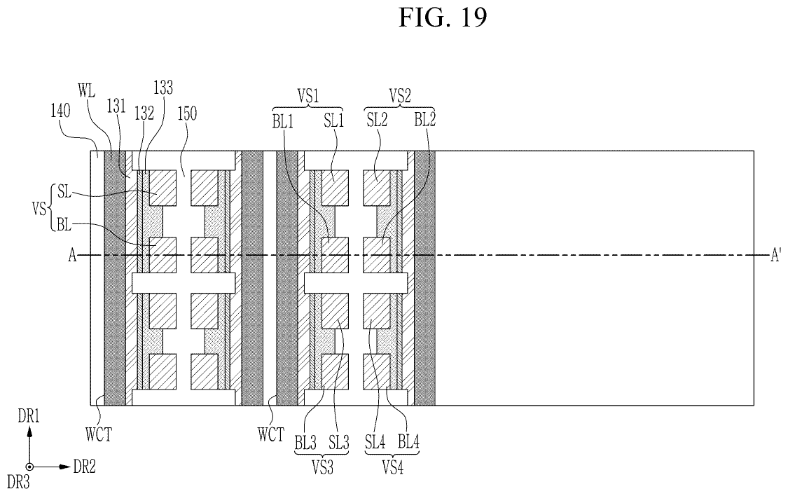

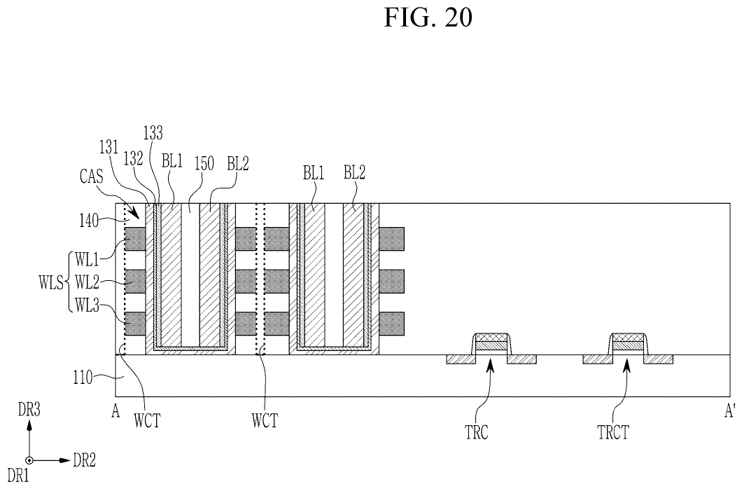

Referring to FIG. 19 and FIG. 20, a word line cut trench WCT penetrating the plurality of first insulating layers ILD1 and the plurality of second insulating layers ILD2 in the third direction DR3 may be formed between the ferroelectric layers 131. The word line cut trench WCT may have a line shape that extends in the first direction DR1. Side surfaces of the plurality of first insulating layers ILD1 and the plurality of second insulating layers ILD2 may be exposed by the word line cut trench WCT.

Subsequently, the plurality of second insulating layers ILD2 may be replaced with the plurality of word lines WL1, WL2, and WL3. According to some example embodiments, the plurality of second insulating layers ILD2 may be selectively removed by providing an etchant having a high etch selectivity with respect to the second insulating layer ILD2 among the first insulating layer ILD1 and the second insulating layer ILD2 through the word line cut trench WCT. The plurality of word lines WL1, WL2, and WL3 may be formed by filling a conducting material within a region where the plurality of second insulating layers ILD2 are removed. The word line structure WLS in which the plurality of word lines WL1, WL2, and WL3 are stacked in the third direction DR3 may be formed at one side of each of the vertical portions of the ferroelectric layer 131. For example, the plurality of word lines WL1, WL2, and WL3 may include at least one selected from a doped semiconductor material, conductive metal nitride, a metal, and a metal-semiconductor compound.

The cell array structure CAS may be formed by processes shown in FIGS. 12 to 20. The cell array structure CAS may include the plurality of ferroelectric layers 131 spaced apart and disposed in the second direction DR2. The cell array structure CAS may include the plurality of gate insulating layers 132 respectively surrounded by the plurality of ferroelectric layers 131, the plurality of channel layers 133, the plurality of vertical structures VS1, VS2, VS3, and VS4, and the insulating pattern 150. The cell array structure CAS may include word line structures WLS adjacent to the outside of each of the plurality of ferroelectric layers 131.

Next, an insulating material layer may be formed within the word line cut trench WCT. According to some example embodiments, the insulating material layer filling the word line cut trench WCT may include the same insulating material as that of the first insulating layer ILD1. Accordingly, the insulating material layers filling word line cut trenches WCT and the first insulating layers ILD1 disposed between the plurality of word lines WL1, WL2, and WL3 may form an integral cell insulating layer 140. The cell insulating layer 140 may surround the cell array structure CAS. The cell insulating layer 140 may cover the converter transistor TRC and the control transistor TRCT disposed on the substrate 110 at the outside of the cell array structure CAS.

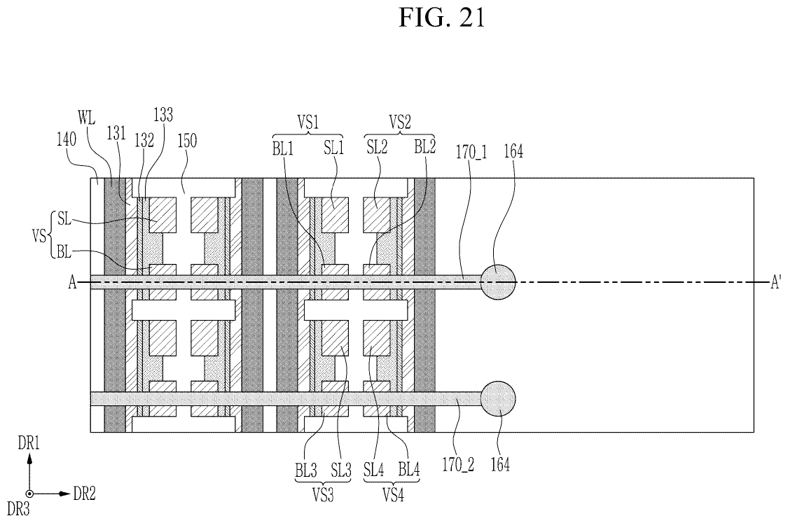

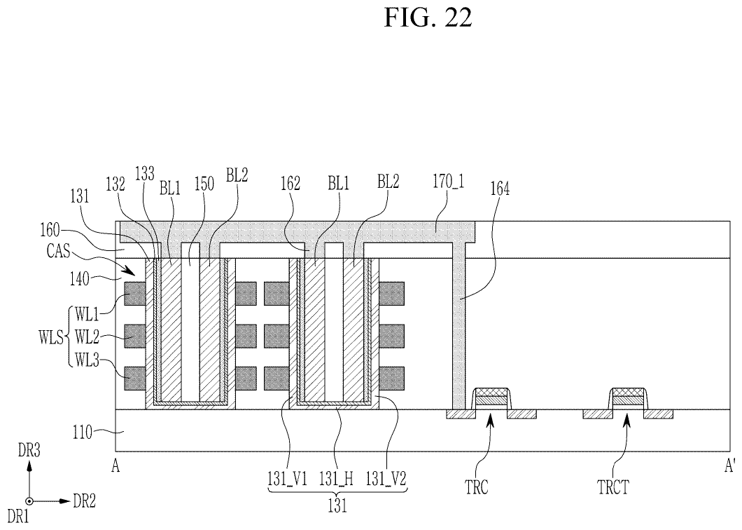

Referring to FIG. 21 and FIG. 22, the first interlayer insulating layer 160 and the plurality of bit line connection wires 170_1 and 170_2 extending in the second direction DR2 may be formed above or on the cell array structure CAS and the cell insulating layer 140.

According to some example embodiments, an insulating material layer may be deposited through a deposition process such as chemical vapor deposition (CVD) or physical vapor deposition (PVD), and a plurality of contact holes penetrating the insulating material layer in the third direction DR3 may be formed. An upper surface of the bit line BL may be exposed by the contact hole.

Subsequently, a conductive material layer may be deposited to fill the plurality of contact holes. The conducting material layer may fill the plurality of contact holes, and may cover an upper surface of the insulating material layer. As the conducting material layer is filled within the plurality of contact holes, the plurality of bit line contacts 162 may be formed.

Next, the conducting material layer may be patterned to form the plurality of bit line connection wires 170_1 and 170_2 with line shapes passing through contact holes spaced apart along the second direction DR2. The plurality of bit line connection wires 170_1 and 170_2 and the plurality of bit lines BL may be connected by the plurality of bit line contacts 162. According to some example embodiments, the plurality of bit line connection wires 170_1 and 170_2 may include the first bit line connection wire 170_1 connecting the first bit lines BL1 and the second bit lines BL2 spaced apart from each other in the second direction DR2, and the second bit line connection wire 170_2 connecting the third bit lines BL3 and the fourth bit lines BLA spaced apart from each other in the second direction DR2.

Next, an insulating material layer may be further deposited to form the first interlayer insulating layer 160. The first interlayer insulating layer 160 may surround side surfaces of the plurality of bit line contacts 162, and may be disposed between the plurality of bit line connection wires 170_1 and 170_2.

According to some example embodiments, the through via 164 penetrating the cell insulating layer 140 to connect each of the plurality of bit line connection wires 170_1 and 170_2 to the converter transistor TRC may be formed. For example, a through hole penetrating each of the plurality of bit line connection wires 170_1 and 170_2, the first interlayer insulating layer 160, and the cell insulating layer 140 may be formed, and the through via 164 may be formed by depositing a conductive material layer within the through hole. Each of the plurality of bit line connection wires 170_1 and 170_2 may be connected to the converter transistor TRC of each of the plurality of analog-to-digital converters by the through via 164.

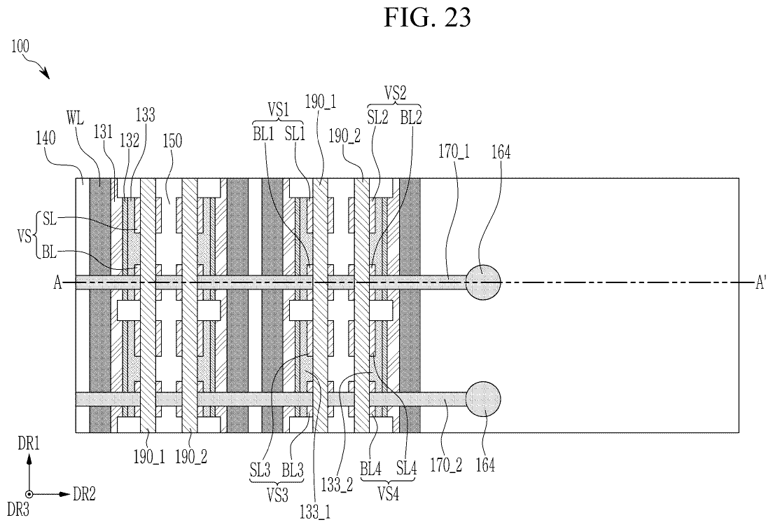

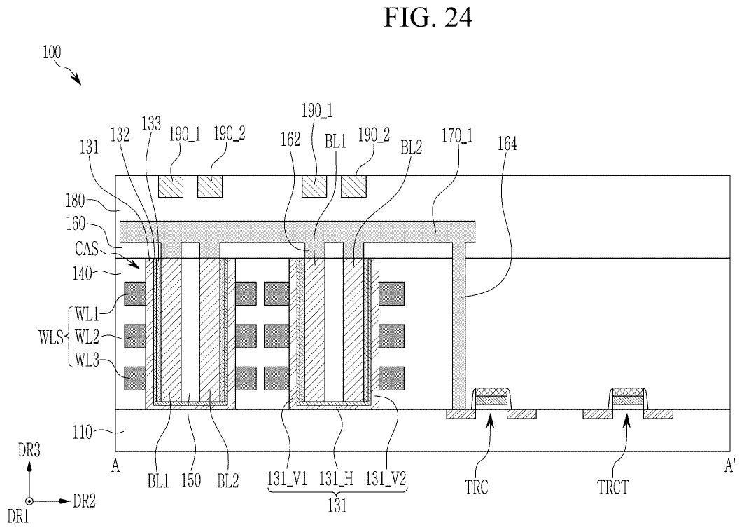

Referring to FIG. 23 and FIG. 24, the second interlayer insulating layer 180 and the plurality of source line connection wires 190_1 and 190_2 extending in the first direction DR1 may be formed above or on the plurality of bit line connection wires 170_1 and 170_2 and the first interlayer insulating layer 160.

According to some example embodiments, an insulating material layer may be deposited through a deposition process such as chemical vapor deposition (CVD) or physical vapor deposition (PVD), and a plurality of contact holes penetrating the insulating material layer in the third direction DR3 may be formed. An upper surface of the source line SL may be exposed by the contact hole.

Subsequently, a conductive material layer may be deposited to fill the plurality of contact holes. The conducting material layer may fill the plurality of contact holes, and may cover an upper surface of the insulating material layer. As the conducting material layer is filled within the plurality of contact holes, the plurality of source line contacts may be formed.

Next, the conducting material layer may be patterned to form the plurality of source line connection wires 190_1 and 190_2 with line shapes passing through contact holes spaced apart along the first direction DR1. The plurality of source line connection wires 190_1 and 190_2 and the plurality of source lines SL may be connected by the plurality of source line contacts. According to some example embodiments, the plurality of source line connection wires 190_1 and 190_2 may include the first source line connection wires 190_1 connecting the first source line SL1 and the third source line SL3 spaced apart from each other along the first direction DR1, and the second source line connection wires 190_2 connecting the second source line SL2 and the fourth source line SL4 spaced apart from each other in the first direction DR1.

Subsequently, an insulating material layer may be further deposited to form the second interlayer insulating layer 180. The second interlayer insulating layer 180 may surround side surfaces of the plurality of source line contacts, and may be disposed between the plurality of source line connection wires 190_1 and 190_2.

According to some example embodiments, a through via penetrating the cell insulating layer 140 to connect each of the plurality of source line connection wires 190_1 and 190_2 to the control transistor TRCT may be formed. For example, a through hole penetrating each of the plurality of source line connection wires 190_1 and 190_2, the second interlayer insulating layer 180, the first interlayer insulating layer 160, and the cell insulating layer 140 may be formed, and a through via may be formed by depositing a conductive material layer within the through hole. Each of the plurality of source line connection wires 190_1 and 190_2 may be connected to the control transistor TRCT of the control circuit by the through via.

The semiconductor device 100 according to some example embodiments may be formed by the processes shown in FIGS. 9 to 24. The semiconductor device 100 may include the cell array structure CAS and the control transistor TRCT of the control circuit CU controlling the cell array structure CAS. The semiconductor device 100 may include the converter transistor TRC of the analog-to-digital converter ADC connected between the cell array structure CAS and the control circuit CU. The semiconductor device 100 may include the plurality of bit line connection wires 170_1 and 170_2, and the plurality of source line connection wires 190_1 and 190_2. Each of the plurality of bit line connection wires 170_1 and 170_2 may connect the bit lines BL spaced apart in the second direction DR2 of the cell array structure CAS to the converter transistor TRC. Each of the plurality of source line connection wires 190_1 and 190_2 may connect the source lines SL spaced apart in the first direction DR1 of the cell array structure CAS to the control transistor TRCT.

While this disclosure has been described in connection with what is presently considered to be some example embodiments, it is to be understood that the disclosure is not limited to the disclosed example embodiments, but, on the contrary, is intended to cover various modifications and equivalent arrangements included within the spirit and scope of the appended claims.

What is claimed is:

1. A semiconductor device comprising:
a substrate including a cell region and a peripheral circuit region;
a vertical structure extending in a direction perpendicular to an upper surface of the substrate at the cell region, the vertical structure including a bit line and a source line spaced apart in a first direction parallel to the upper surface of the substrate;
a word line extending in the first direction at one side of the vertical structure;
a channel layer between the bit line and the word line, and between the source line and the word line, the channel layer being connected between the bit line and the source line;
a ferroelectric layer between the word line and the channel layer;
a control circuit on the substrate at the peripheral circuit region;
a source line connection wire connected to the source line and the control circuit; and
a bit line connection wire connected to the bit line and the control circuit, wherein the source line connection wire and the bit line connection wire cross on a plane.

2. The semiconductor device of claim 1, wherein the source line connection wire and the bit line connection wire are spaced apart in the direction perpendicular to the upper surface of the substrate by an interlayer insulating layer.

3. The semiconductor device of claim 1, further comprising:
an analog-to-digital converter on the substrate and connected between the bit line and the control circuit,
wherein the bit line connection wire is connected to the analog-to-digital converter.

4. The semiconductor device of claim 3, further comprising:
a cell array structure that includes the vertical structure and a word line structure, the word line structure including a plurality of word lines stacked in the direction perpendicular to the upper surface of the substrate, the ferroelectric layer and the channel layer between the vertical structure and the word line structure;
a cell insulating layer that surrounds the cell array structure; and
a through via that penetrates the cell insulating layer connecting the bit line connection wire to the analog-to-digital converter.

5. The semiconductor device of claim 4, wherein
the control circuit, the analog-to-digital converter, and a peripheral circuit insulating layer covering the analog-to-digital converter and the control circuit are on the substrate,
the cell array structure and the cell insulating layer are on the peripheral circuit insulating layer,
the bit line connection wire and the source line connection wire are stacked above the cell array structure and the cell insulating layer, and
the through via further penetrates the peripheral circuit insulating layer.

6. The semiconductor device of claim 5, further comprising:
a plurality of cell blocks; and
a summing circuit,
wherein each of the plurality of cell blocks includes the cell array structure and the analog-to-digital converter connected to the cell array structure, and
the summing circuit is connected between the analog-to-digital converter of each of the plurality of cell blocks and the control circuit.

7. The semiconductor device of claim 1, wherein
the ferroelectric layer includes a horizontal portion parallel to the upper surface of the substrate, the ferroelectric layer includes a first vertical portion and a second vertical portion, and the first vertical portion and the second vertical portion perpendicular to the upper surface of the substrate and spaced apart in a second direction crossing the first direction, and
a plurality of vertical structures between the first vertical portion and the second vertical portion.

8. The semiconductor device of claim 7, wherein
the plurality of vertical structures includes a first vertical structure and a second vertical structure spaced apart in the second direction,
a first source line of the first vertical structure and a second source line of the second vertical structure face each other in the second direction,
a first bit line of the first vertical structure and a second bit line of the second vertical structure face each other in the second direction, and
the bit line connection wire connects the first bit line and the second bit line.

9. The semiconductor device of claim 8, wherein
the plurality of vertical structures further includes a third vertical structure spaced apart from the first vertical structure in the first direction and a fourth vertical structure spaced apart from the second vertical structure in the first direction,
the first source line of the first vertical structure and a third source line of the third vertical structure are parallel in the first direction,
the second source line of the second vertical structure and a fourth source line of the fourth vertical structure are parallel in the first direction, and
the source line connection wire includes a first source line connection wire connecting the first source line and the third source line and a second source line connection wire connecting the second source line and the fourth source line.

10. The semiconductor device of claim 9, further comprising:
a plurality of word line structures,
wherein each of the plurality of word line structures includes a plurality of word lines stacked in the direction perpendicular to the upper surface of the substrate,
the plurality of word line structures includes a first word line structure at one side of the first vertical portion of the ferroelectric layer and a second word line structure at one side of the second vertical portion of the ferroelectric layer, and
the first word line structure and the second word line structure are on opposite side surfaces of the first vertical portion and the second vertical portion, the side surfaces being spaced apart in the second direction.

11. The semiconductor device of claim 10, further comprising:
a plurality of channel layers,
wherein the plurality of channel layer includes,
a first channel layer between the first word line structure and the first vertical structure and between the second word line structure and the second vertical structure,
a second channel layer between the first word line structure and the third vertical structure and between the second word line structure and the fourth vertical structure, and
the first channel layer and the second channel layer are spaced apart in the first direction.

12. The semiconductor device of claim 11, wherein the first vertical portion of the ferroelectric layer is between the first word line structure and the first channel layer and between the first word line structure and the second channel layer, and
the second vertical portion of the ferroelectric layer is between the second word line structure and the first channel layer and between the second word line structure and the second channel layer.

13. A semiconductor device comprising:
a substrate including a cell region and a peripheral circuit region;
a vertical structure extending in a direction perpendicular to an upper surface of the substrate at the cell region, the vertical structure including a bit line and a source line spaced apart in a first direction parallel to the upper surface of the substrate;
a word line extending in the first direction at one side of the vertical structure;
a channel layer between the bit line and the word line and between the source line and the word line, the channel layer being connected between the bit line and the source line;
a ferroelectric layer between the word line and the channel layer;
a control circuit on the substrate at the peripheral circuit region; and
a source line connection wire and a bit line connection wire extending in a direction parallel to the upper surface of the substrate, the source line connection wire and the bit line connection wire are stacked above the vertical structure,
wherein the source line connection wire extends in the first direction, and the bit line connection wire extends in a second direction orthogonal to the first direction.

14. The semiconductor device of claim 13, wherein the source line connection wire and the bit line connection wire are spaced apart in the direction perpendicular to the upper surface of the substrate by an interlayer insulating layer.

15. The semiconductor device of claim 13, further comprising:
an analog-to-digital converter on the substrate and connected between the bit line and the control circuit,
wherein the bit line connection wire is connected to the analog-to-digital converter.

16. The semiconductor device of claim 13, wherein
the ferroelectric layer includes a horizontal portion parallel to the upper surface of the substrate, a first vertical portion, and a second vertical portion perpendicular to the upper surface of the substrate, the first vertical portion and the second vertical portion spaced apart in the second direction, and
a plurality of vertical structures are between the first vertical portion and the second vertical portion.

17. The semiconductor device of claim 16, wherein
the plurality of vertical structures includes a first vertical structure and a second vertical structure spaced apart in the second direction,
a first source line of the first vertical structure and a second source line of the second vertical structure face each other in the second direction,
a first bit line of the first vertical structure and a second bit line of the second vertical structure face each other in the second direction, and
the bit line connection wire extends along the second direction above the first vertical structure and the second vertical structure and connects the first bit line and the second bit line.

18. The semiconductor device of claim 17, wherein
the plurality of vertical structures further includes a third vertical structure spaced apart from the first vertical structure in the first direction and a fourth vertical structure spaced apart from the second vertical structure in the first direction,
the first source line of the first vertical structure and a third source line of the third vertical structure are parallel in the first direction,
the second source line of the second vertical structure and a fourth source line of the fourth vertical structure are parallel in the first direction, and
the source line connection wire includes a first source line connection wire connecting the first source line and the third source line and a second source line connection wire connecting the second source line and the fourth source line.

19. A semiconductor device comprising:
a substrate including a cell region and a peripheral circuit region;
a vertical structure extending in a direction perpendicular to an upper surface of the substrate at the cell region, the vertical structure including a bit line and a source line spaced apart in a first direction parallel to the upper surface of the substrate;
a word line extending in the first direction at one side of the vertical structure;
a channel layer between the bit line and the word line and between the source line and the word line, the channel layer being connected between the bit line and the source line;
a ferroelectric layer between the word line and the channel layer;
a control circuit on the substrate at the peripheral circuit region;
an analog-to-digital converter on the substrate and connected to the control circuit;
a source line connection wire above the vertical structure and connected to the source line and the control circuit; and
a bit line connection wire above the vertical structure and connected to the bit line and the analog-to-digital converter,
wherein the source line connection wire and the bit line connection wire are at different layers, one of the source line connection wire and the bit line connection wire extends in a direction parallel to the word line, and an other of the source line connection wire and the bit line connection wire extends in a direction crossing the word line.

20. The semiconductor device of claim 19, wherein the source line connection wire and the bit line connection wire are spaced apart in the direction perpendicular to the upper surface of the substrate.
